(19) United States
(12) Patent Application Publication
(10) Pub. No.: US 2005/0153545 A1
(43) Pub. Date: Jul. 14, 2005

(54) Methods of forming copper interconnections using electrochemical plating processes

(76) Inventor: Ji Ho Hong, Suwon (KR)

Correspondence Address: HANLEY, FLIGHT & ZIMMERMAN, LLC, 20 N. WACKER DRIVE, SUITE 4220, CHICAGO, IL, 60606, US

(21) Appl. No.: 11/027,514

(22) Filed: Dec. 30, 2004

(30) Foreign Application Priority Data
Dec. 31, 2003 (KR) 10-2003-0102211

(51) Int. Cl. H01L 21/4763; H01L 21/44

(52) U.S. Cl. 438/650; 438/677; 438/678; 438/653; 438/687

(57) ABSTRACT

Methods of forming a copper interconnect using an ECP process is disclosed. One disclosed method includes forming a barrier metal layer on the surface of a single or dual damascene structure; forming a silver layer as a seed layer on the surface of the barrier metal layer; forming a Cu layer on the silver layer by performing an ECP process using the silver layer as the seed layer; and performing an annealing process and a chemical mechanical polishing process for the Cu layer to form a Cu interconnect.

### TECHNICAL FIELD

The present disclosure relates generally to semiconductor fabrication and, more particularly, to methods of forming copper interconnections using electrochemical plating (ECP) processes.

### BACKGROUND

To form a copper (Cu) interconnection using an ECP process, a seed layer with low-resistivity is generally required. Therefore, a Cu seed layer formed by a physical vapor deposition process (PVD) has been mainly used as the seed layer.

As the integration of semiconductor devices advances, the dimension of an interconnection has to be miniaturized and, therefore, a thin Cu seed layer is desired. However, the thinner the Cu seed layer is, the higher its electrical resistance. The increased resistance generates a terminal effect while the ECP process is conducted to form a Cu interconnect. Such a thermal effect deteriorates the uniformity of the completed seed layer and detrimentally affects other characteristics of the semiconductor device.

In particular, the thermal effect makes it difficult to control the uniformity of the seed layer in a process for a large size wafer such as a 300 millimeter (mm) diameter wafers instead of 200 mm wafers. Thus, the seed layer is required to have low electrical resistivity regardless of the diminution of the interconnection.

### BRIEF DESCRIPTION OF THE DRAWINGS

FIGS. 1a through 1d are cross-sectional views illustrating an example semiconductor device at various stages of a disclosed Cu interconnect formation process.

### DETAILED DESCRIPTION

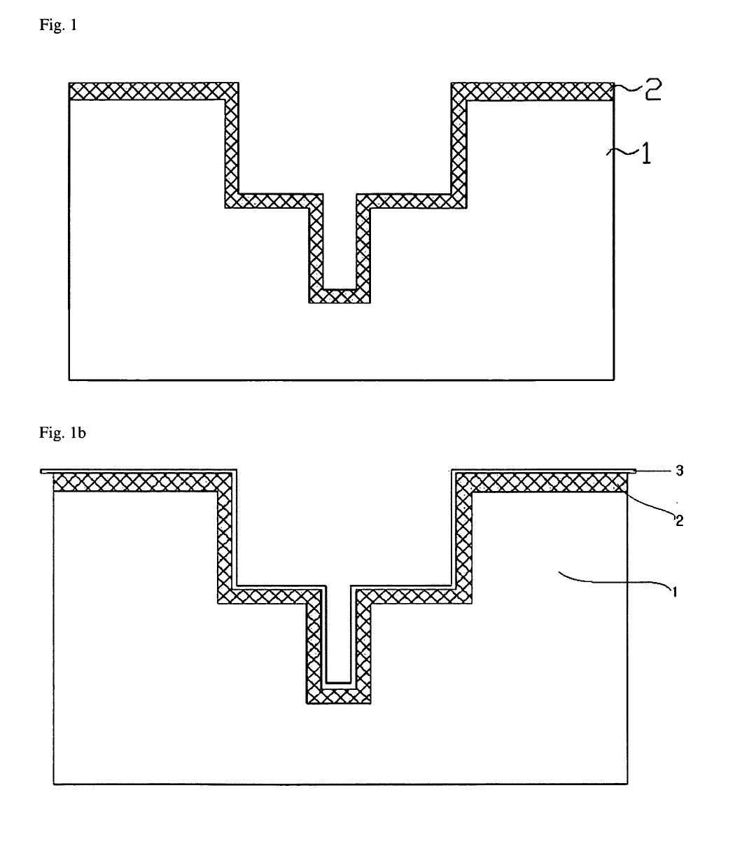

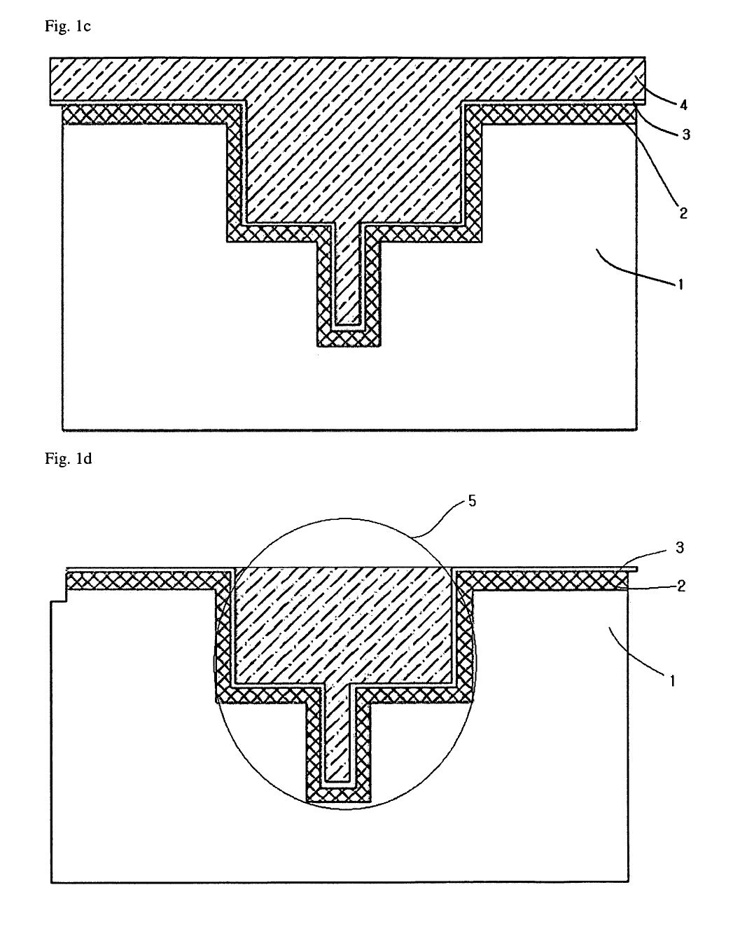

Referring to FIG. 1a, a barrier metal layer 2 is formed on an insulating layer 1 of a single or dual damascene structure. The barrier metal layer 2 prevents the reaction between a Cu layer use as an interconnection (not shown) and the insulating layer 1 of the single or dual damascene structure. In one particular example, the barrier metal layer is typically made of TiN.

Referring to FIG. 1b, a silver layer 3 as a seed layer is formed on the surface of the barrier metal layer 2 by performing a process selected from the group consisting of an ElectroLess Plating (ELP) process, an ECP process, a Physical Vapor Deposition (PVD) process, a Chemical Vapor Deposition (CVD) process, and an Atomic Layer Deposition (ALD) process. The silver layer 3 maintains low resistivity even at a thin thickness, thereby improving the shortcomings of the conventional Cu seed layer.

Referring to FIG. 1c, a Cu layer 4 is formed using the silver layer 3 as the seed layer in the ECP process.

Referring to FIG. 1d, an annealing process is performed for the Cu layer 4 on the silver layer 3 and, thus, the Cu layer 4 becomes thermally stabilized. Subsequently, the upper part of the Cu layer 4 is planarized by a chemical mechanical polishing (CMP) process and a Cu interconnection 5 is then completed.

Disclosed herein are methods of forming a copper interconnection by the ECP process by forming the silver layer as the seed layer, thereby preventing the deterioration of the uniformity of the seed layer.

It is noted that this patent claims priority from Korean Patent Application Serial Number 10-2003-0102211, which was filed on Dec. 31, 2003, and is hereby incorporated by reference in its entirety.

Although certain example methods, apparatus, and articles of manufacture have been described herein, the scope of coverage of this patent is not limited thereto. On the contrary, this patent covers all methods, apparatus, and articles of manufacture fairly falling within the scope of the appended claims either literally or under the doctrine of equivalents.

1. A method of forming a copper interconnection using an electrochemical plating process comprising:
forming a barrier metal layer on the surface of a single or dual damascene structure;
forming a silver layer as a seed layer on the surface of the barrier metal layer;
forming a copper layer on the silver layer by performing an electrochemical plating process using the silver layer as the seed layer; and
performing an annealing process and a chemical mechanical polishing process on the copper layer to form a copper interconnect.

2. A method defined by claim 1, wherein the silver layer is formed by performing a process selected from the group consisting of an ElectroLess Plating process, an ElectroChemical Plating process, a Physical Vapor Deposition process, a Chemical Vapor Deposition process, and an Atomic Layer Deposition process.
